(19) United States
(12) Patent Application Publication
(10) Pub. No.: US 2023/0301016 A1
(43) Pub. Date: Sep. 21, 2023

(54) STAND HAVING FANS FOR LAPTOP

(71) Applicant: Cheng Yu Huang, New Taipei (TW)

(72) Inventor: Cheng Yu Huang, New Taipei (TW)

(21) Appl. No.: 17/702,283

(22) Filed: Mar. 23, 2022

(30) Foreign Application Priority Data
Mar. 18, 2022 (TW) 111202718

(51) Int. Cl. H05K 7/20; H05K 7/14; H05K 5/02; G06F 1/20

(52) U.S. Cl. CPC H05K 7/20172; H05K 7/1427; H05K 5/0234; G06F 1/203

(57) ABSTRACT

A stand includes a body, sliding front and rear extending frames, first and second pivotal supports at two sides respectively, and two third pivotal supports at two sides of the sliding lower extending frame. The first, second and third pivotal supports are each capable of pivoting to dispose the body in an acute angle with respect to a supporting surface or rest the body on the supporting surface. The sliding front and rear extending frame each include a cross member and two sliding rods disposed at two ends of the cross member respectively, each sliding rod extending into the body. An angle of the stand with respect to the supporting surface is adjustable.

### FIELD OF THE INVENTION

The invention relates to stands and more particularly to a stand having fans for a laptop, the stand being angle adjustable.

### BACKGROUND OF THE INVENTION

Consumer electronic devices such as computers, tablet computers, mobile communication devices, etc. are very popular among consumers due to lightness, portability, multi-function and extended period of time of use.

Laptops are characterized by lightweight, compactness, and portability and are so-called portable computers. However, the laptops are not on a par with personal computers in terms of heat dissipation due to smaller size and crowded space.

Heat accumulation is not a problem when a laptop operates for a short period of time. However, components of the laptop (e.g., hard disk drive and/or CPU) may malfunction due to overheat. Further, a user of the laptop may be hurt. Furthermore, there is no angle adjustment mechanism of a stand for the laptop. Thus, the laptops are not ergonomic. A typical stand of the laptop projects downward and in turn, it may hinder the hands' operation.

There are a wide variety of stands for laptop commercially available or disclosed in patent literature. For example, the present inventor owns U.S. Pat. Nos. 8,662,465 and 8,699,221 both capable of adjusting an angle of a stand. However, they are structurally complicated and bulky, resulting in inconvenience of carrying to an outdoor environment and in use. Thus, the need for improvement still exists.

### SUMMARY OF THE INVENTION

It is therefore one object of the invention to provide a stand, comprising a body, a sliding front extending frame at a front end, a sliding rear extending frame at a rear end, a first pivotal support at one side, a second pivotal support at the other side, and two third pivotal supports at two sides of the sliding lower extending frame; wherein the first, second and third pivotal supports are each capable of pivoting to dispose the body in an acute angle with respect to a supporting surface or rest the body on the supporting surface; wherein the body includes a cover, a base releasably secured to the cover, two internal fans, and an internal PCB electrically connected to the fans and having a USB port and a fan speed adjustment knob; wherein the sliding front extending frame includes a cross member and two sliding rods disposed at two ends of the cross member respectively, each sliding rod extending into the body; wherein the sliding rear extending frame includes a cross member and two sliding rods disposed at two ends of the cross member respectively, each sliding rod extending into the body; wherein the cross member includes two spaced, elongated holes on a top; wherein the sliding front extending frame further comprises two cavities in the cross member and two slip-resistant posts configured to moveably dispose in the holes or the cavities respectively; wherein the sliding rear extending frame further comprises two spaced recesses on a top of the cross member and two pivotal arms configured to dispose in the recesses respectively in a first position or pivot to partially dispose out of the recesses respectively in a second position; and wherein the pivotal arm includes an arc shaped surface at one end and a snapping surface adjacent to the arc shaped surface.

Preferably, the sliding front extending frame further comprises two pivotal members each disposed at a bottom of the sliding rod adjacent to the cross member; the pivotal members each include a main element and a pivotal element pivotably secured to the main element; in a first configuration, the sliding rods extend out of the body, the pivotal members are pivoted to dispose out of the sliding rods respectively, and the pivotal element is received in the main element so that the body is disposed at a first angle with respect to the supporting surface; in a second configuration, the sliding rods extend out of the body, the pivotal members are pivoted to dispose out of the sliding rods respectively, and the pivotal element is pivoted out of the main element so that the body is disposed at a second angle with respect to the supporting surface.

Preferably, there is further provided with two grooved rails at two sides of the body respectively, the grooved rails configured to receive the sliding rods and the sliding rods respectively.

The above and other objects, features and advantages of the invention will become apparent from the following detailed description taken with the accompanying drawings

### BRIEF DESCRIPTION OF THE DRAWINGS

FIG. 1 is a perspective view of a stand for laptop of the invention;

FIG. 2 is a perspective view of the sliding front and rear extending frames being fully extended, viewed from top;

FIG. 3 is a perspective view of the sliding front and rear extending frames being fully extended, viewed from bottom;

FIG. 4 is an exploded view of the stand;

FIG. 5 a bottom plan view of the stand;

FIG. 6 is a view similar to FIG. 5, the sliding front and rear extending frames being fully extended;

FIG. 7 is a perspective view of the stand disposed at a first angle with respect to the supporting surface;

FIG. 8 is a perspective view of the stand disposed at a second angle with respect to the supporting surface;

FIG. 9A is a perspective view of the pivotal member;

FIG. 9B is an exploded view of the pivotal member;

FIG. 10 is a view similar to FIG. 7 with a laptop rested thereon;

FIG. 11 is a view similar to FIG. 8 with the laptop rested thereon;

FIG. 12 is a view similar to FIG. 1 with the second pivotal support pivoted so that the heat removal function of the fans can be fully performed;

FIG. 13 is a perspective view of the stand with the third pivotal supports pivoted so that the stand is disposed vertically, viewed from the bottom; and

FIG. 14 is a perspective view of the stand with the third pivotal supports pivoted so that the stand is disposed vertically, viewed from the top.

### DETAILED DESCRIPTION OF THE INVENTION

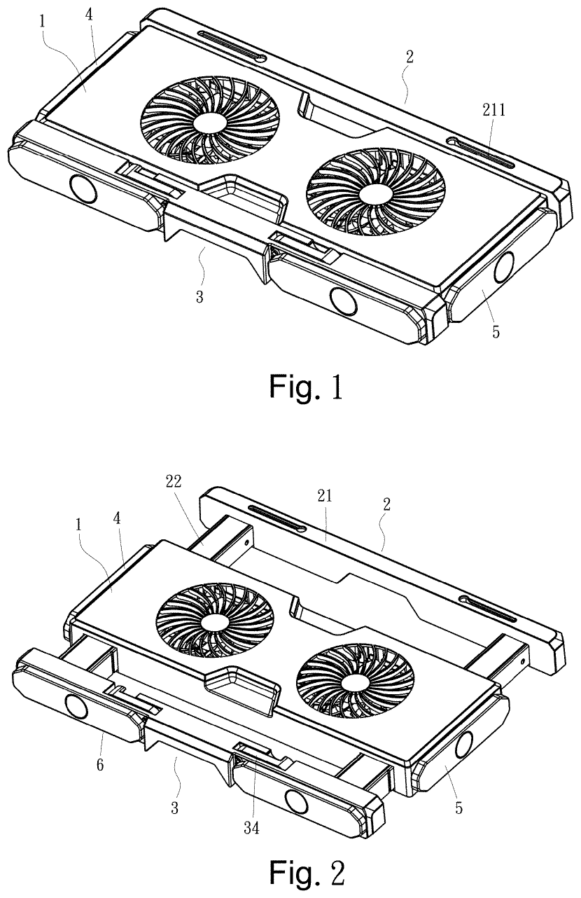

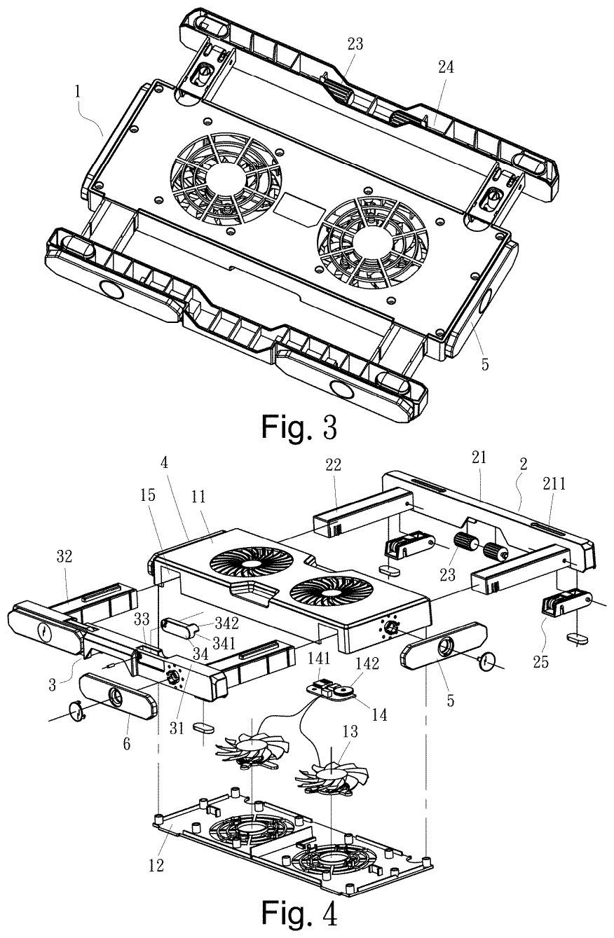

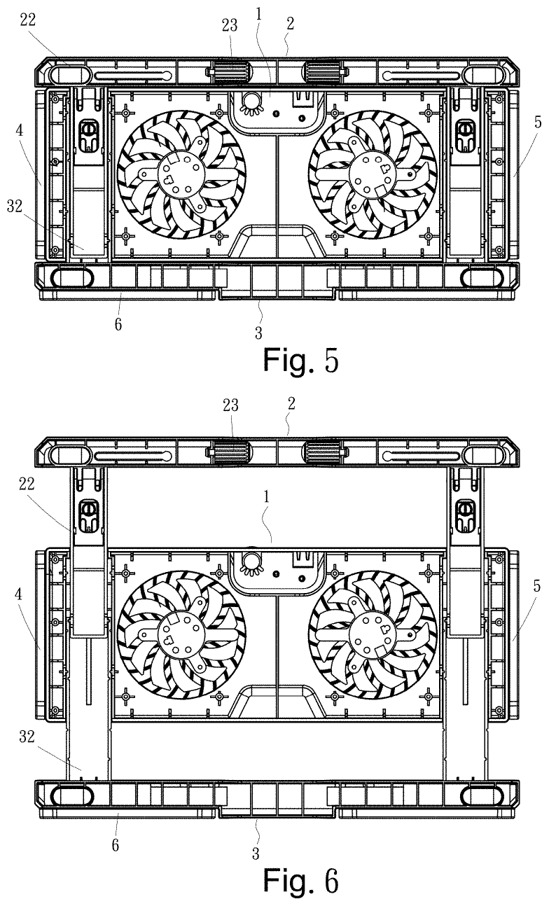

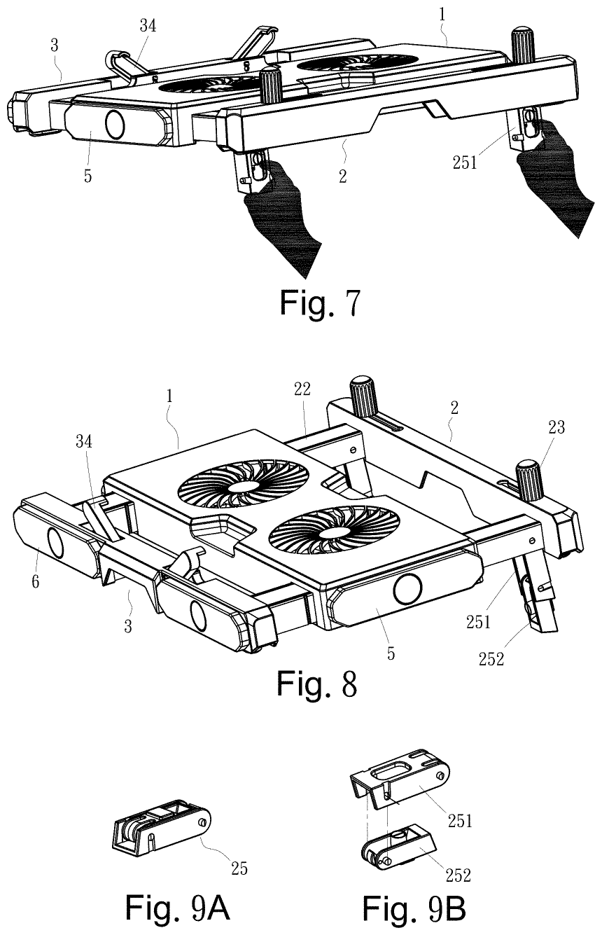

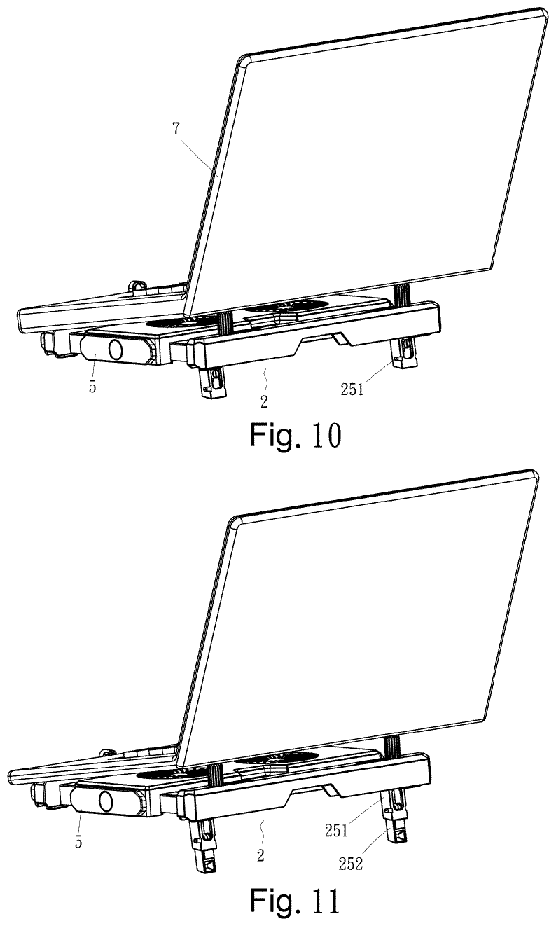

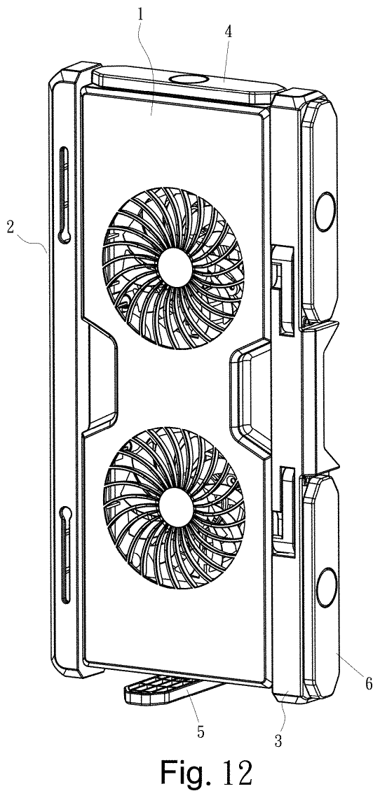

Referring to FIGS. 1 to 14, a stand for a laptop 7 in accordance with the invention comprises a body 1, a sliding front extending frame 2 at a front end, a sliding rear extending frame 3 at a rear end, a first pivotal support 4 at one side, a second pivotal support 5 at the other side, and two third pivotal supports 6 at two sides of the sliding lower extending frame 3 respectively as discussed in detail below.

The first, second and third pivotal supports 4, 5 and 6 are each capable of pivoting to dispose the body 1 in an acute angle with respect to the supporting surface or rest the body 1 on the supporting surface.

The body 1 includes a cover 11, a base 12 releasably secured to the cover 11 to form a housing, two internal fans 13, an internal printed circuit board (PCB) 14 electrically connected to the fans 13 and having a universal serial bus (USB) port 141 as power input and a fan speed adjustment knob 142, and two grooved rails 15 at two sides of the body 1 respectively.

The sliding front extending frame 2 includes a cross member 21 and two sliding rods 22 disposed at two ends of the cross member 21 respectively and each extending into the grooved rail 15. The sliding rear extending frame 3 includes a cross member 31 and two sliding rods 32 disposed at two ends of the cross member 31 respectively and each extending into the grooved rail 15.

On a top of the cross member 21 there are provided two spaced, elongated holes 211. Two slip-resistant posts 23 are moveably disposed in the holes 211 respectively in use or disposed in two cavities 24 in the cross member 21.

Two pivotal members 25 each are provided at a bottom of the sliding rod 22 adjacent to the cross member 21. The pivotal member 25 includes a main element 251 and a pivotal element 252 pivotably secured to the main element 251. In a first position, the sliding rods 22 extend out of the grooved rails 15, the pivotal members 25 are pivoted to dispose out of the sliding rod 22, and the pivotal element 252 is received in the main element 251 so that the body 1 is disposed at a first angle with respect to the supporting surface. In a second position, the sliding rods 22 extend out of the grooved rails 15 respectively, the pivotal members 25 are pivoted to dispose out of the sliding rods 22 respectively, and the pivotal element 252 is pivoted out of the main element 251 so that the body 1 is disposed at a second angle with respect to the supporting surface.

The sliding rear extending frame 3 further comprises two spaced recesses 33 on a top of the cross member 31 and two pivotal arms 34 disposed in the recesses 33 respectively in a first position or pivoted to partially dispose out of the recesses 33 respectively in a second position. The pivotal arm 34 includes an arc shaped surface 341 at one end and a snapping surface 342 adjacent to the arc shaped surface 341. The provision of the snapping surface 342 and the arc shaped surface 341 positions the laptop 7 rested thereon and facilitate the operation of the laptop 7 by the hands.

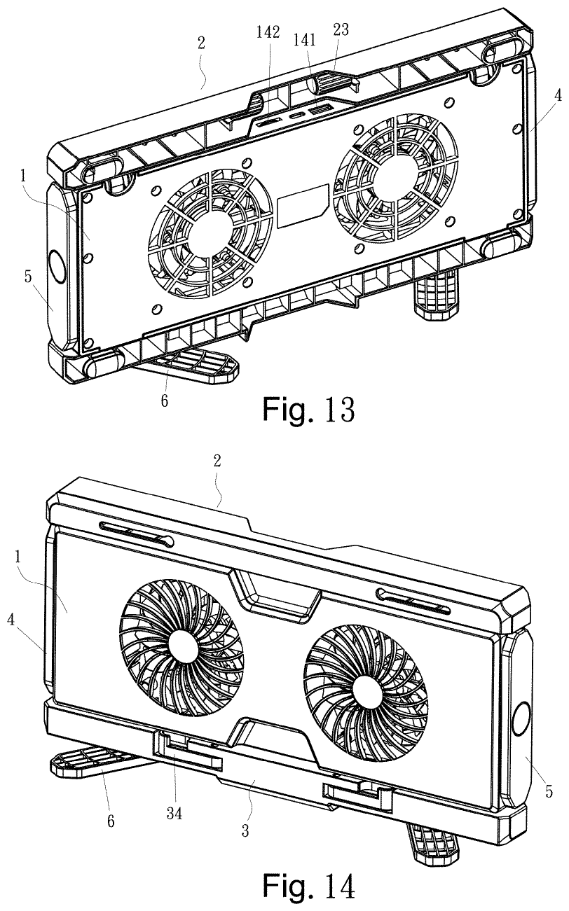

As shown in FIGS. 13 and 14 specifically, the stand is disposed vertically by pivoting the third pivotal supports 6 in another configuration.

While the invention has been described in terms of preferred embodiments, those skilled in the art will recognize that the invention can be practiced with modifications within the spirit and scope of the appended claims.

What is claimed is:

1. A stand, comprising a body (1), a sliding front extending frame (2) at a front end, a sliding rear extending frame (3) at a rear end, a first pivotal support (4) at one side, a second pivotal support (5) at the other side, and two third pivotal supports (6) at two sides of the sliding lower extending frame (3);
wherein the first, second and third pivotal supports (4, 5, 6) are each capable of pivoting to dispose the body (1) in an acute angle with respect to a supporting surface or rest the body (1) on the supporting surface;
wherein the body (1) includes a cover (11), a base (12) releasably secured to the cover (11), two internal fans (13), and an internal PCB (14) electrically connected to the fans (13) and having a USB port (141) and a fan speed adjustment knob (142);
wherein the sliding front extending frame (2) includes a cross member (21) and two sliding rods (22) disposed at two ends of the cross member (21) respectively, each sliding rod (22) extending into the body (1);
wherein the sliding rear extending frame (3) includes a cross member (31) and two sliding rods (32) disposed at two ends of the cross member (31) respectively, each sliding rod (32) extending into the body (1);
wherein the cross member (21) includes two spaced, elongated holes (211) on a top;
wherein the sliding front extending frame (2) further comprises two cavities (24) in the cross member (21) and two slip-resistant posts (23) configured to moveably dispose in the holes (211) or the cavities (24) respectively;
wherein the sliding rear extending frame (3) further comprises two spaced recesses (33) on a top of the cross member (31) and two pivotal arms (34) configured to dispose in the recesses (33) respectively in a first position or pivot to partially dispose out of the recesses (33) respectively in a second position; and
wherein the pivotal arm (34) includes an arc shaped surface (341) at one end and a snapping surface (342) adjacent to the arc shaped surface (341).

2. The stand of claim 1, wherein the sliding front extending frame (2) further comprises two pivotal members (25) each disposed at a bottom of the sliding rod (22) adjacent to the cross member (21); wherein the pivotal members (25) each include a main element (251) and a pivotal element (252) pivotably secured to the main element (251); wherein in a first configuration, the sliding rods (22) extend out of the body (1), the pivotal members (25) are pivoted to dispose out of the sliding rods (22) respectively, and the pivotal element (252) is received in the main element (251) so that the body (1) is disposed at a first angle with respect to the supporting surface; and wherein in a second configuration, the sliding rods (22) extend out of the body (1), the pivotal members (25) are pivoted to dispose out of the sliding rods (22) respectively, and the pivotal element (252) is pivoted out of the main element (251) so that the body (1) is disposed at a second angle with respect to the supporting surface.

3. The stand of claim 1, further comprising two grooved rails (15) at two sides of the body (1) respectively, the grooved rails (15) configured to receive the sliding rods (22) and the sliding rods (32) respectively.
